(19) United States
(12) Patent Application Publication
(10) Pub. No.: US 2004/0055999 A1
(43) Pub. Date: Mar. 25, 2004

(54) Method for planarizing polysilicon

(76) Inventors: Yu-Cheng Chen, Taipei (TW); Jia-Xing Lin, Taipei (TW); Chi-Lin Chen, Hsinchu (TW)

Correspondence Address: BIRCH STEWART KOLASCH & BIRCH, PO BOX 747, FALLS CHURCH, VA, 22040-0747, US

(21) Appl. No.: 10/358,184

(22) Filed: Feb. 5, 2003

(30) Foreign Application Priority Data
Sep. 19, 2002 (TW) 91121425

(51) Int. Cl. C23F 1/00; B44C 1/22; C03C 15/00; C03C 25/68

(52) U.S. Cl. 216/57

(57) ABSTRACT

The present invention relates to a method for planarizing polysilicon. The method includes providing a substrate with polysilicon on the surface, etching the surface of the polysilicon to initially reduce surface roughness, and laser annealing the polysilicon to partially melt the polysilicon to planarize the surface thereof.

### BACKGROUND OF THE INVENTION

1. Field of the Invention

The present invention relates to a method for planarizing polysilicon. In particular, the invention involves the planarization of polysilicon by etching and laser annealing to reduce surface roughness, thus producing high quality thin film transistor (TFT) of polysilicon. This method is applicable in polysilicon TFT processes, such as low temperature polysilicon (LTPS) TFT.

2. Description of the Related Art

Polysilicon thin film transistor (TFT) has been widely used in various fields, such as active matrix liquid crystal displays (LCDs), active matrix organic Light-Emitting Displays, static random access memory (SRAM), projectors and contact type image sensors.

In the current polysilicon TFT process, a problem is surface roughness, even more serious when grain size of the polysilicon continues to increase. This is not advantageous for the electrical properties of the devices, such as breakdown electrical field, leakage current, subthreshold swing, threshold voltage and mobility of electron/hole.

Surface roughness of polysilicon directly impacts product quality and yield. Hence, in a semiconductor process where gate insulator is formed on the polysilicon, as shown in FIG. 1, uneven thickness of the polysilicon results in irregular thickness of the gate insulator layer as well. Thus, ridges in the polysilicon layer 10 induce greater local electrical field. This shortcoming increases the leakage current, thereby causing easier breakdown of gate insulator 12. Reliability of devices is adversely affected, even more seriously for thin gate insulator device.

Furthermore, in the photolithography process, surface roughness of polysilicon causes disorder scattering, thereby resulting in inaccuracy of pattern size definition. This increases the difficulty associated with pattern definition during the process.

In connection with the surface roughness of polysilicon, there are a number of research papers proposing the improvement of electrical characteristics by reducing the surface roughness of polysilicon. Examples of such papers are “Fabrication of Thin Film Transistors by Chemical Mechanical Polished Polycrystalline Silicon Films” by C. Y. Chang, published in Electron Device letters, vol. 17, No. 3, March 1996 of IEEE (International Electrical and Electronic Engineering). Chang stated that surface roughness (RMS) of polysilicon is decreased from 90 angstroms to 37 angstroms by chemical mechanical polishing (CMP). This provides improvement in electron/hole mobility, threshold voltage, and subthreshold swing. Moreover, “Improved Thin-Film Transistor (TFT) Characteristics on Chemical-Mechanically Polished Polycrystalline Silicon Film” written by Alain C. K. Chan, published in IEEE Electron Devices Meeting 1999 Proceedings, June 1999, indicated that surface roughness of polysilicon improved by CMP has positive effect on performance of TFT devices.

The trends of flat panel display manufacture are the use of large-area substrates, and fabrication of smaller devices, such as LTPS-TFTs, to allow mass production. Dimensions of the substrate can reach 1 m×1 m or more. Therefore, applicability of a planarization method for greater dimensions polysilicon substrates must be considered. Current planarization using CMP is limited in this regard, as no CMP equipment is designed for use with the larger size. Consequently, CMP is no longer applicable in the future for mass production with larger polysilicon substrate dimensions. Furthermore, surface roughness after CMP is still between 30 and 40 angstoms, not satisfactory for further advancements in reducing dimensions of TFT devices. Thus, a planarization method for polysilicon that is can be used with larger polysilicon substrates and is capable of providing additional improvements for the surface roughness is in great demand.

### SUMMARY OF THE INVENTION

To overcome the above problems, an object of the invention is to provide a method for planarizing polysilicon that can be used with larger polysilicon substrates. Major features of the method include etching the polysilicon to change its surface morphology, which involves the removal of native oxide, weak bonded silicon, and impurities in the polysilicon to initially lower the surface roughness. This is followed by laser annealing to partially melt the polysilicon so that the surface of polysilicon is reconstructred to form a smooth surface. By adjusting etching and laser annealing, extreme smooth polysilicon surface can be obtained.

In order to achieve the above objects, there is provided a method for planarizing polysilicon, involving providing a substrate formed with polysilicon on the surface, changing surface morphology of the polysilicon by etching to initially reduce surface roughness, and laser annealing the polysilicon to partially melt and thereby planarize the surface thereof.

In the method of the present invention, the substrate can be glass, quartz, silicon wafer, plastic or silicon on insulator (SOI). That is, the method provided in the invention is applicable with any substrate formed with polysilicon on the surface.

In the method described above, etching is carried out by either wet or dry etching. Preferable solution for wet etching is buffered oxide etchant (BOE) or diluted hydrogen fluoride (DHF). Dry etching is not limited to a particular method, as long as unwanted substances such as native oxide, weak bonded silicon and impurities on the polysilicon are removed. As for laser annealing, parameters are varied based on different laser equipment. Laser annealing is performed so that polysilicon is partially melted for lattice reconstruction, thus forming a smooth surface.

According to the method of the present invention, after the polysilicon surface is modified by etching, laser annealing is then carried out to obtain a smooth surface. The advantages include greatly-reduced surface roughness and applicability for larger polysilicon substrates.

The present invention will become more fully understood from the detailed description given hereinbelow and the accompanying drawings, given by way of illustration only and thus not intended to be limitative of the present invention.

### BRIEF DESCRIPTION OF THE DRAWINGS

FIG. 1 is TEM photograph of the polysilicon before planarization and gate insulator layer.

FIG. 2 illustrates the process flow for the method for planarizing polysilicon according to the method of the present invention.

FIG. 3 illustrates the reduced surface roughness for the method according to the embodiment of the present invention.

FIG. 4A is the TEM photograph of the original polysilicon before planarization.

FIG. 4B is the TEM photograph showing the polysilicon having reduced surface roughness according to the embodiment of the present invention.

FIG. 5A is an AFM stereograph of the original polysilicon before planarization.

FIG. 5B is an AFM stereograph of the polysilicon according to the embodiment of the present invention.

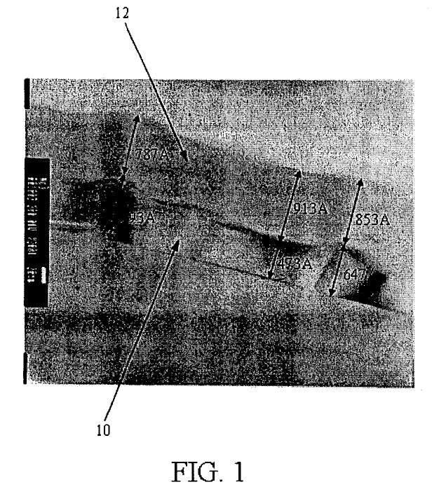

### DETAILED DESCRIPTION OF THE INVENTION

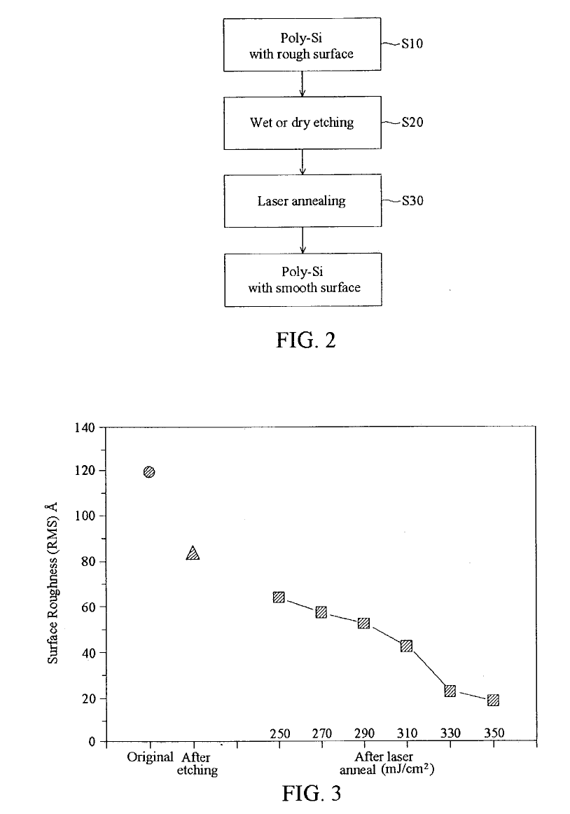

FIG. 2 illustrates the process flow of the method for planarizing polysilicon of the present invention.

Firstly, a substrate formed with polysilicon on the surface is provided as step S10. Formation of the polysilicon is not restricted to any particular method, and laser crystallization or chemical vapor deposition are both acceptable. Next, in step S20, etching is carried out to change the surface structure of the polysilicon. In this embodiment, buffered oxide etchant (BOE) is used as the etching solution. In this step, native oxide, weak bonded silicon and impurities in the polysilicon surface are removed. Components of the BOE solution are HF, NH₄F and H₂O. A preferable ratio of the BOE to water is 1:300˜1:0. If other etching solution, such as diluted hydrogen fluoride (DHF) is used, the preferable ratio of hydrogen fluoride to water is 1:600˜1:1. Preferable time for wet etching is less than 600 sec. Optionally, dry etching is applicable as well, such as plasma etching using CF₄ gas.

Next, the polysilicon is subjected to laser annealing as step S30. Excimer laser is adopted in this embodiment. Relevant parameters are: the repeated pulse overlap ratio is preferably 98%; 1 atm Nitrogen is the preferable surrounding; frequency is preferably 1 Hz to 400 Hz, and more preferably 200 Hz; wavelength is preferably 157 nm to 351 nm, and more preferably 308 nm; energy density is preferably lower than the threshold energy density for polysilicon to completely melt, i.e. 250˜350 mJ/cm²; time for laser pulse is preferably 10 ns to 1 ms, and more preferably 55 ns; and preferable temperature of the substrate is room temperature to 600° C.

The laser annealing step allows partial melting of the polysilicon surface, and consequently the lattice structure is reconstructed. The surface of the polysilicon is thus planarized to reduce surface roughness. Parameters, such as temperature, pressure, laser energy are varied according to the type of equipment used.

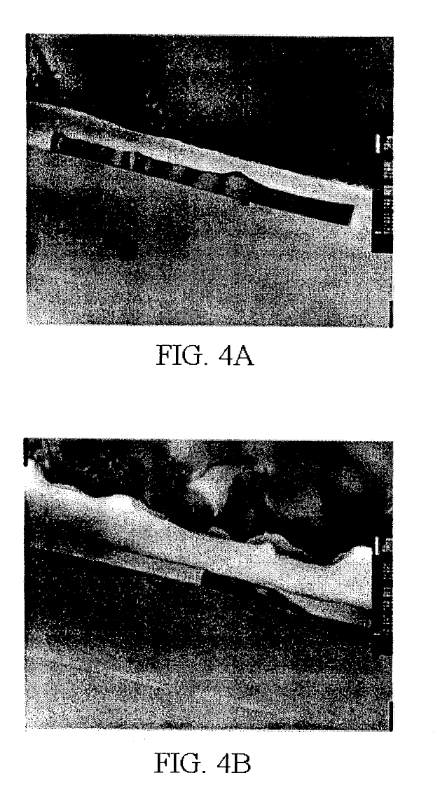

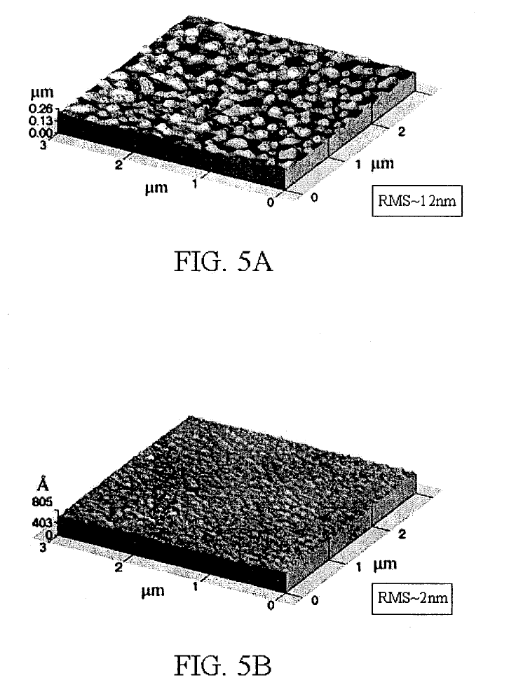

FIG. 4A is the TEM photograph of the original polysilicon before planarization. FIG. 4B is the TEM photograph showing the polysilicon having reduced surface roughness according to the embodiment of the present invention. FIG. 5A is an AFM stereograph of the original polysilicon before planarization. FIG. 5B is an AFM stereograph of the polysilicon according to the embodiment. It is observed from FIG. 4A that ridges in the original polysilicon are planarized in FIG. 4B. A very smooth polysilicon surface is obtained without ridges between the polysilicon and the gate insulator layer.

Similarly, surface roughness of polysilicon is greatly reduced from 120 angstroms to 18 angstroms, only 15% of the original surface roughness, as shown in FIGS. 5A and 5B. In comparison to the conventional method using CMP, where surface roughness is reduced by 50%, the method provided in the present invention provide excellent results of planarizing polysilicon.

From the above results and FIG. 3, which illustrates the gradual results of planarizing polysilicon, original polysilicon (●), after etching (▴) and laser annealing (▪), surface roughness (RMS) of polysilicon is reduced by 30-95%. Generally, surface roughness (RMS) is reduced to less than 20 angstroms. Therefore, it is concluded that the method for planarizing polysilicon provided in the present invention is capable of obtaining polysilicon with a smoother surface. Furthermore, this method is not limited by the dimensions of the substrate, and can be easily adopted in the LTPS TFT process.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for planarizing polysilicon, comprising:
providing a substrate with polysilicon on the surface;
changing the surface structure of the polysilicon by etching to initially reduce surface roughness; and
subjecting the polysilicon to laser annealing for partial melting of the polysilicon to planarize the surface.

2. The method as claimed in claim 1, wherein the etching step removes native oxide, weak bonded silicon, and impurities form the polysilicon surface.

3. The method as claimed in claim 1, wherein the etching is dry etching.

4. The method as claimed in claim 1, wherein the etching is wet etching.

5. The method as claimed in claim 4, wherein the wet etching is carried out by buffered oxide etchant or diluted hydrogen fluoride.

6. The method as claimed in claim 5, wherein the ratio of the buffered oxide etchant to water is 1:300˜1:0.

7. The method as claimed in claim 5, wherein the ratio of the diluted hydrogen fluoride to water is 1:600˜1:1.

8. The method as claimed in claim 4, wherein the time for wet etching is less than 600 sec.

9. The method as claimed in claim 3, wherein the dry etching is carried out by plasma etching with CF₄ gas.

10. The method as claimed in claim 1, wherein the wavelength of the laser pulse for laser annealing is 157˜351 nm.

11. The method as claimed in claim 1, wherein the wavelength of the laser pulse for laser annealing is 308 nm.

12. The method as claimed in claim 1, wherein the time of laser pulse for the laser annealing is 10 ns˜1 ms.

13. The method as claimed in claim 1, wherein the duration time of laser pulse for the laser annealing is 55 ns.

14. The method as claimed in claim 1, wherein the temperature of the substrate for the laser annealing is room temperature to 600° C.

15. The method as claimed in claim 1, wherein the frequency of laser pulse for the laser annealing is 1 Hz to 400 Hz.

16. The method as claimed in claim 1, wherein the frequency of laser pulse for the laser annealing is 200 Hz.

17. The method as claimed in claim 1, wherein the energy of the laser annealing is lower than the threshold energy for polysilicon to melt completely.

18. The method as claimed in claim 1, wherein the energy density of the laser annealing step is 250˜350 mJ/cm².

19. The method as claimed in claim 1, wherein the substrate is glass, quartz, Si wafer, plastic or silicon on insulator (SOI).
